(19) United States
(12) Patent Application Publication
(10) Pub. No.: US 2014/0138842 A1
(43) Pub. Date: May 22, 2014

(54) CONTINUOUS VIA FOR POWER GRID

(71) Applicant: INTERNATIONAL BUSINESS MACHINES CORPORATION, Armonk, NY (US)

(72) Inventor: James D. Warnock, Somers, NY (US)

(73) Assignee: International Business Machines Corporation, Armonk, NY (US)

(21) Appl. No.: 13/680,862

(22) Filed: Nov. 19, 2012

(51) Int. Cl. H01L 23/48; H01L 21/768

(52) U.S. Cl. CPC H01L 23/481; H01L 21/768
USPC 257/774; 438/637

(57) ABSTRACT

A power grid of a Very Large Scale Integration (VLSI) circuit includes a sandwich structure in a cell. The sandwich structure includes a first metal layer configured to carry current along a lateral axis, and a second metal layer, parallel to the first metal layer with a gap therebetween. The second metal layer carries current along a second lateral axis which is parallel to the lateral axis of the first metal layer. The sandwich structure also includes interconnect material disposed as a continuous via throughout the gap, the continuous via interconnecting the first metal layer and the second metal layer throughout the gap.

### BACKGROUND

The present invention relates to Very Large Scale Integration (VLSI) circuits, and, more specifically, to a power grid of a VLSI circuit.

VLSI circuits are made up of interconnected cells that include a group of transistors and interconnect structures. Each cell must be powered from the VLSI circuit power supply through a power grid. The power grid of the VLSI circuit refers to the wires or buses used to supply current to the logic devices of each cell and to ground buses used to take current away.

As the lithography dimension of integrated circuits (ICs) is scaled to smaller sizes, creating reliable wiring becomes more challenging. This is because of factors such as non-scaling of the supply voltage, which leads to non-scaling of the electrical currents in the interconnects, non-scaling of the reliability lifetime of wires, where the reliability of wires drops rapidly as the dimension is scaled even at a constant current density, and increasing temperatures associated with higher power densities. If the local wire interconnects to the circuits cannot be scaled beyond some limits, then the physical area occupied by the circuit cannot be reduced and overall scalability suffers. The power and ground wires become significant in the endeavor to produce smaller integrated circuits because they carry direct current (DC) and are, therefore, subject to electromigration failures which decrease the reliability of integrated circuits.

One conventional approach has been to widen the power wires where necessary and/or to decrease the spatial periodicity of the power and ground buses. However, this solution results in less room for signal wires and, therefore, leads to lower circuit densities. Another approach has been to use a “sandwich structure” which duplicates power wires on vertically adjacent layers. A number of discrete vias or “via farms” provide connectivity between the two metal layers of the sandwich. While this approach helps with distribution of the power and ground wires, it does not provide maximum wire volume in the physical space allocated to the structure. Thus, a power grid that provides a reliable wiring solution and increases current carrying capability within the available space would be appreciated in the IC industry.

### SUMMARY

According to one embodiment, a sandwich structure in a cell of a Very Large Scale Integration (VLSI) circuit includes a first metal layer configured to carry current along a lateral axis; a second metal layer, parallel to the first metal layer with a gap therebetween, the second metal layer configured to carry current along a second lateral axis which is parallel to the lateral axis of the first metal layer; and interconnect material disposed as a continuous via throughout the gap, the continuous via interconnecting the first metal layer and the second metal layer throughout the gap.

According to another embodiment, a method of creating a sandwich structure in a Very Large Scale Integration (VLSI) circuit cell includes disposing a first metal layer and a second metal layer parallel to each other with a gap therebetween; and interconnecting the first metal layer and the second metal layer with interconnect material in a continuous via layer throughout the gap.

According to yet another embodiment, a power grid of a Very Large Scale Integration (VLSI) circuit includes a first metal layer configured to carry current along a lateral axis; a second metal layer, parallel to the first metal layer with a gap therebetween, the second metal layer configured to carry current along a second lateral axis which is parallel to the lateral axis of the first metal layer; and interconnect material disposed as a continuous via throughout the gap, the continuous via interconnecting the first metal layer and the second metal layer throughout the gap.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a top view of a continuous via sandwich structure according to an embodiment;

FIG. 2 shows a cross-sectional view along A-A′ of the continuous via sandwich structure shown at FIG. 1;

FIG. 3 shows a cross-sectional view along B-B′ of the continuous via sandwich structure shown at FIG. 1;

FIG. 4 shows a cross-sectional view of a continuous via sandwich structure according to another embodiment; and

FIG. 5 depicts exemplary processes involved in forming a continuous via sandwich structure according to an embodiment.

### DETAILED DESCRIPTION

VLSI circuits include metal layers (levels) in each cell that are used for routing or interconnections within the cell and among cells. While vertically adjacent metal layers are typically used for routing in perpendicular directions, at least the first two metal layers may be parallel to each other, depending on the structure of the cells and the requirements for power and ground connections. Thus, these first two levels may lend themselves to the sandwich structure. Also, with parallel first and second metal layers, if the first metal level is used for local interconnects inside the gates of the cell transistors, the concept of a “wrong-way” (i.e., lengthwise perpendicular to other wires routed on the same metal layer) power bus does not apply. As noted above, previous attempts to duplicate power wires on the first and second metal levels have involved the placement of a number of vias between the two levels. However, while these vias increased the connectivity between the two metal levels facilitating the vertical flow of current from the top metal layer down to the bottom, they did not increase the lateral current carrying capacity of the structure because the discrete vias cannot allow lateral current flow (lateral being along the axial length of each of the parallel metal levels and perpendicular to each via axial length).

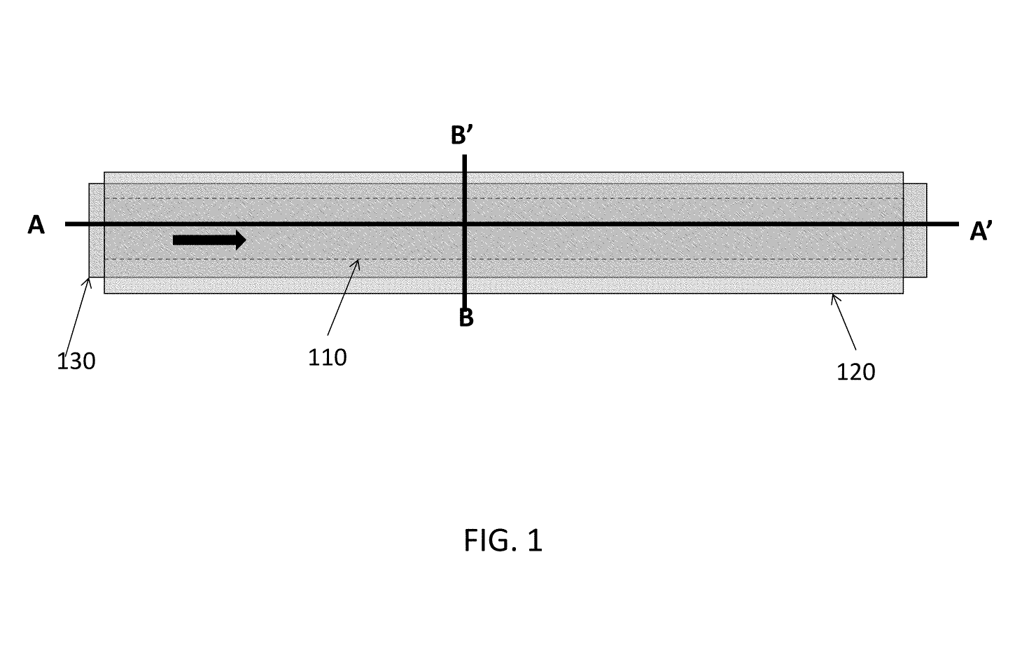

FIG. 1 illustrates a top view of a continuous via sandwich structure 100 according to an embodiment. The sandwich structure 100 may pertain to a logic gate or a cell within the VLSI circuit. The arrow indicates a direction of current flow through the second metal level 120 and is intended to highlight that current flow is along the lateral axial rather than limit a direction of current flow. FIG. 1 also shows portions of the first (lower) metal level 130. The first metal level 130 is parallel to the second metal layer 120, and current flows along the lateral axis of the first metal level 130, as well. The continuous via 110 (shown with a dashed line) is a solid layer connecting the first metal level 130 and the second metal level 120 rather than a set of discrete vias that provide connectivity between the first metal level 120 and the second metal level 130. Thus all three layers 110, 120, and 130 may conduct lateral current, and adjacent cells, designed with similar structures, may be connected together on the first metal layer 130, the second metal layer 120, and the continuous via layer 110, such that current may flow unimpeded through all three layers 110, 120, 130, across rows of adjacent cells. When the sandwich structure 100 shown by FIG. 1 is rotated by 90 degrees, with circuits arranged in columns instead of rows, the sandwich structure 100 is still the same in all essential ways, and it is only the viewer's frame of reference which is different.

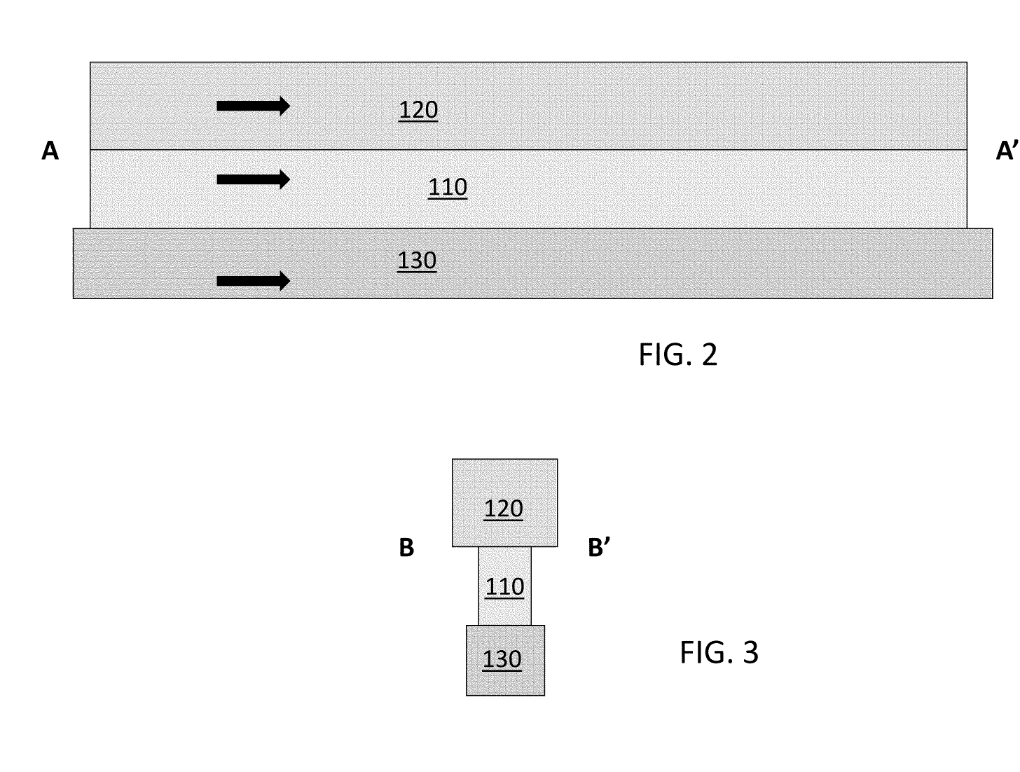

FIG. 2 shows a cross-sectional view along A-A′ of the continuous via sandwich structure 100 shown at FIG. 1. FIG. 2 shows the continuous via 110 formed as a solid interconnect layer throughout the gap that separates the first metal level 130 and the second metal level 120. The continuous via 110 between the first metal level 130 and the second metal level 120 facilitates lateral current flow (the lateral axis being indicated by the arrow) in all three levels 110, 120, 130 rather than only in the first metal level 130 and the second metal level 120. Current may flow unimpeded through all three layers 110, 120, 130 across rows of adjacent cells. As a result, the current carrying capacity is increased in a space that would normally be occupied by only two current-carrying layers (the first metal level 130 and the second metal level 120). One of the consequences of the continuous via sandwich structure 100 and the increased current-carrying capacity that it provides is increased signal wire space elsewhere within the cell. This is because, for a given current requirement, the sandwich structure 100 can now be made narrower than otherwise required without the increased current-carrying capability of the continuous via 110 layer.

FIG. 3 shows a cross-sectional view along B-B′ of the continuous via sandwich structure 100 shown at FIG. 1. Significantly, FIG. 3 would look the same regardless of where along the lateral axis of the first metal level 130 and the second metal level 120 the B-B′ cross-section were taken.

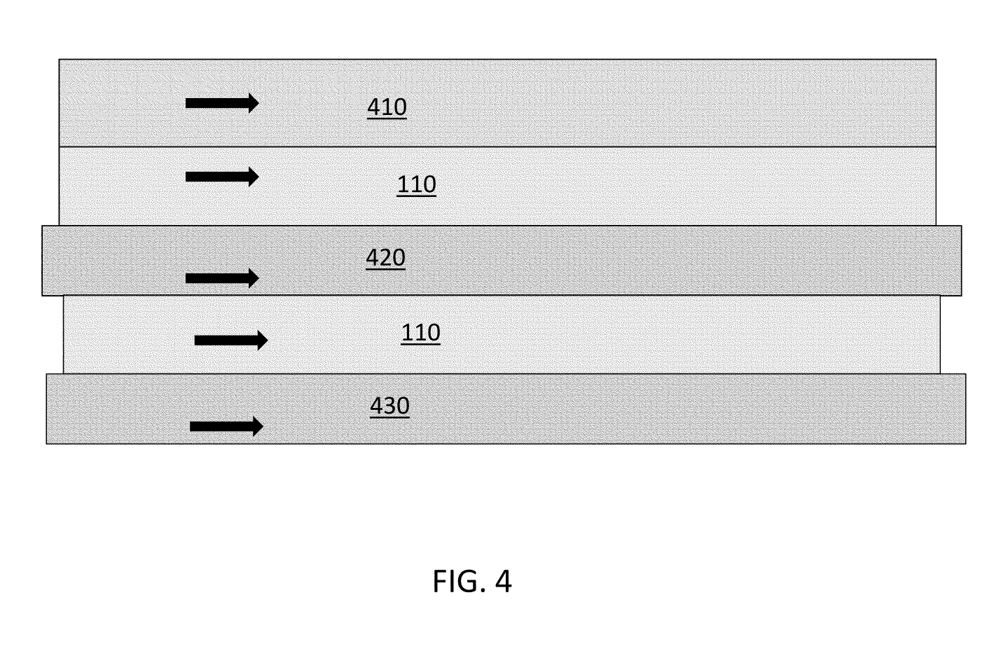

FIG. 4 shows a cross-sectional view of a continuous via sandwich structure 400 according to another embodiment. The embodiment shown by FIG. 4 includes 3 metal layers 410, 420, 430 joined by layers of continuous vias 110. Although FIG. 4 shows three metal layers 410, 420, 430, any number of metal layers may be joined by layers of continuous vias 110. Further, the continuous via 110 may carry any common signals shared across adjacent cells. That is, in addition to supplying current for power and ground connections, the continuous via 110 may carry other supply voltages or act as a virtual, or other pseudo-ground wire, where the effective ground plane connected to the rows of circuits is separated from the real electrical ground level to allow it to be controlled separately during circuit operation. The continuous via 110 may carry signals, as well.

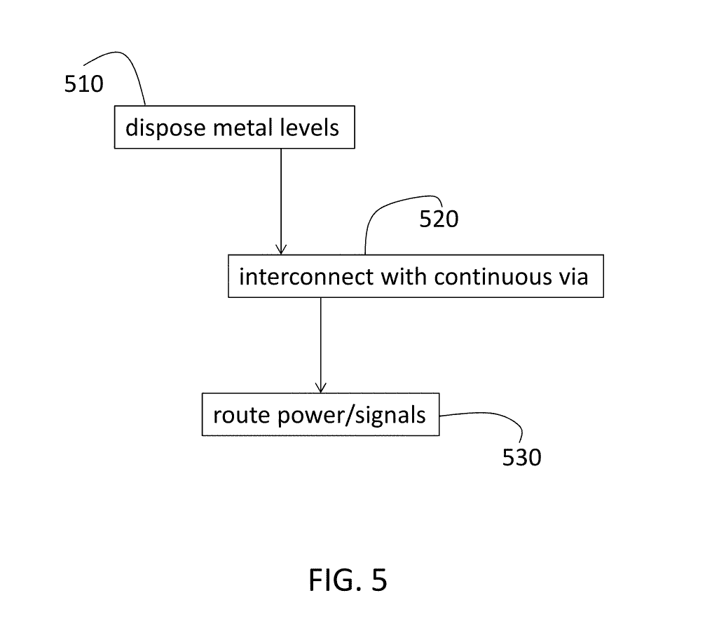

FIG. 5 depicts exemplary processes 500 involved in forming a continuous via sandwich structure according to an embodiment. The processes 500 include disposing the metal levels in the cell at block 510. In one embodiment, as shown at FIGS. 1-3, two metal levels 120, 130 may be formed in parallel. In other embodiments, for example, as shown at FIG. 4, three or more metal levels 410, 420, 430 may be formed in parallel. At block 520, the processes 500 include interconnecting the parallel metal levels with continuous via layers 110. When a sandwich structure is formed with a continuous via layer 110, power or signals may be routed through the continuous via layer 110, as shown at block 530.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagram depicted herein is just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. A sandwich structure in a cell of a Very Large Scale Integration (VLSI) circuit, comprising:
a first metal layer configured to carry current along a first lateral axis;
a second metal layer, parallel to the first metal layer with a gap therebetween, the second metal layer configured to carry current along a second lateral axis which is parallel to the first lateral axis; and
interconnect material disposed as a continuous via throughout the gap, the continuous via interconnecting the first metal layer and the second metal layer throughout the gap.

2. The structure according to claim 1, wherein the continuous via carries current along a via lateral axis, the via lateral axis being parallel to the first lateral axis and the second lateral axis.

3. The structure according to claim 1, wherein the continuous via carries a signal common to the cell and an adjacent cell.

4. The structure according to claim 1, wherein the continuous via supplies a voltage.

5. The structure according to claim 1, further comprising a third metal layer parallel to the second metal layer with a second gap between the third metal layer and the second metal layer, and interconnect material disposed as a continuous via layer interconnecting the second metal layer and the third metal layer throughout the second gap.

6-10. (canceled)

11. A power grid of a Very Large Scale Integration (VLSI) circuit, comprising:
a first metal layer configured to carry current along a first lateral axis;
a second metal layer, parallel to the first metal layer with a gap therebetween, the second metal layer configured to carry current along a second lateral axis which is parallel to the first lateral axis; and
interconnect material disposed as a continuous via throughout the gap, the continuous via interconnecting the first metal layer and the second metal layer throughout the gap.

12. The power grid according to claim 11, wherein the continuous via carries current along its lateral axis parallel to the first lateral axis and the second lateral axis.

13. The power grid according to claim 11, wherein the continuous via carries a signal along its lateral axis.

14. The power grid according to claim 11, wherein the first metal layer, the second metal layer, and the continuous via are part of a cell of the VLSI circuit.

15. The power grid according to claim 11, wherein two or more cells of the VLSI circuit include the first metal layer, the second metal layer, and the continuous via.

16. The power grid according to claim 11, further comprising a third metal layer parallel to the second metal layer with a second gap between the third metal layer and the second metal layer, and interconnect material disposed as a continuous via layer interconnecting the second metal layer and the third metal layer throughout the second gap.
